(19) United States
(12) Patent Application Publication
(10) Pub. No.: US 2014/0042549 A1
(43) Pub. Date: Feb. 13, 2014

(54) METHODS OF FORMING STRESS-INDUCING LAYERS ON SEMICONDUCTOR DEVICES

(71) Applicant: Johannes Von Kluge, Dresden (DE)

(72) Inventor: Johannes Von Kluge, Dresden (DE)

(73) Assignee: GLOBALFOUNDRIES INC., Grand Cayman (KY)

(21) Appl. No.: 13/570,410

(22) Filed: Aug. 9, 2012

(51) Int. Cl. H01L 27/092; H01L 21/8238

(52) U.S. Cl. 257/369; 438/692; 257/E27.062; 257/E21.632

(57) ABSTRACT

An illustrative device disclosed herein includes an NFET transistor, a PFET transistor, a tensile stress-inducing layer formed above the NFET transistor, a compressive stress-inducing layer formed above the PFET transistor and a stress relaxation material positioned at least in an opening defined between the tensile stress-inducing layer and the compressive stress-inducing layer.

### BACKGROUND OF THE INVENTION

1. Field of the Invention

Generally, the present disclosure relates to the manufacture of sophisticated semiconductor devices, and, more specifically, to various methods of forming stress-inducing layers of material on semiconductor devices and the resulting devices.

2. Description of the Related Art

The fabrication of advanced integrated circuits, such as CPUs, storage devices, ASICs (application specific integrated circuits) and the like, requires a large number of circuit elements to be formed on a given chip area according to a specified circuit layout, wherein field effect transistors represent one important type of circuit element that substantially determines performance of the integrated circuits. Generally, a plurality of process technologies are currently practiced, wherein, for many types of complex circuitry, including field effect transistors, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors (NFET) and/or P-channel transistors (PFET), are formed on a substrate including a crystalline semiconductor layer. A field effect transistor, irrespective of whether an NFET transistor or a PFET transistor is considered, typically comprises so-called PN junctions that are formed by an interface of highly doped regions, referred to as drain and source regions, with a slightly doped or non-doped region, such as a channel region, disposed adjacent to the highly doped regions.

Device designers are under constant pressure to increase the operating speed and electrical performance of transistors and integrated circuit products that employ such transistors. Given that the gate length (the distance between the source and drain regions) on modern transistor devices may be approximately 30-50 nm, and that further scaling is anticipated in the future, device designers have employed a variety of techniques in an effort to improve device performance, e.g., the use of high-k dielectrics, the use of metal gate electrode structures, the incorporation of work function metals in the gate electrode structure and the use of channel stress engineering techniques on transistors (create a tensile stress in the channel region for NFET transistors and create a compressive stress in the channel region for PFET transistors). Stress engineering techniques typically involve the formation of specifically made silicon nitride layers that are selectively formed above appropriate transistors, i.e., a layer of silicon nitride that is intended to impart a tensile stress in the channel region of an NFET transistor would only be formed above the NFET transistors. Such selective formation may be accomplished by masking the PFET transistors and then blanket depositing the layer of silicon nitride, or by initially blanket depositing the layer of silicon nitride across the entire substrate and then performing an etching process to selectively remove the silicon nitride from above the PFET transistors. Conversely, for PFET transistors, a layer of silicon nitride that is intended to impart a compressive stress in the channel region of a PFET transistor is formed above the PFET transistors. The techniques employed in forming such nitride layers with the desired tensile or compressive stress are well known to those skilled in the art.

FIG. 1A is a simplified view of an illustrative prior art semiconductor device 100 that is formed above a semiconducting substrate 10. The device 100 is generally comprised of an illustrative NFET transistor 100N and an illustrative PFET transistor 100P formed in and above an NFET region 10N and a PFET region 10P, respectively, defined in the substrate 10. The view depicted in FIG. 1A is a cross-sectional view taken in the channel length direction of the devices 100N, 100P, as indicated by the double-arrow 21. The active regions 10N, 10P are defined by illustrative trench isolation structures 12 formed in the substrate 10. The NFET transistor 100N and the PFET transistor 100P each include a schematically depicted gate electrode structure 20, that typically includes a gate insulation layer 20A and a gate electrode 20B, and a plurality of source/drain regions 22N, 22P, respectively, a liner layer 25, sidewall spacers 26, and a plurality of metal silicide regions 24.

In one embodiment, the first desired stress-inducing layer is formed above the PFET device 100P first, although, if desired, the first stress-inducing material layer could be formed above the NFET device 100N. Accordingly, FIG. 1A depicts that a compressive stress-inducing layer 30, a tensile stress-inducing layer 36 and an etch stop layer 32 are formed above the device 100. The layers 30, 36 and 32 may be formed from a variety of materials and they may be formed by performing a variety of known techniques. In one illustrative example, the stress-inducing layers 30, 36 are comprised of silicon nitride while the etch stop layer 32 is comprised of silicon dioxide. The stress-inducing layers 30, 36 may have a thickness of about 50-60 nm, and they may be formed using a chemical vapor deposition (CVD) process, wherein the parameters of the CVD process are adjusted and controlled such that the stress-inducing layers exhibit the desired compressive or tensile stress. The manner in which this is accomplished is well known to those skilled in the art. The purpose of the compressive stress-inducing layer 30 is to impart a desired compressive stress to the channel region of the PFET transistor 100P so as to increase the mobility of the charge carriers, i.e., holes, to thereby improve the electrical performance characteristics of the PFET transistor 100P. The purpose of the tensile stress-inducing layer 36 is to impart a desired tensile stress to the channel region of the NFET transistor 100N so as to increase the mobility of the charge carriers, i.e., electrons, to thereby improve the electrical performance characteristics of the NFET transistor 100N.

The structure depicted in FIG. 1A may be achieved by a variety of different process flows. In one example, the compressive stress-inducing layer 30 and the etch stop layer 32 are blanket deposited across both of the devices 100P, 100N. Thereafter, a masking layer (not shown), e.g., a photoresist mask is formed on the device 100 to cover the PFET transistor 100P while leaving the portions of the compressive stress-inducing layer 30 and the etch stop layer 32 positioned above the NFET transistor 100N exposed for further processing. Thereafter, one or more etching processes are performed to remove the exposed portions of the compressive stress-inducing layer 30 and the etch stop layer 32 from above the NFET transistor 100N. Next, after the masking layer above the PFET device 100P is removed, the tensile stress-inducing layer 36 is blanket deposited across both of the devices 100N, 100P. Thereafter, a masking layer (not shown), e.g., a photoresist mask is formed on the device 100 to cover the NFET transistor 100N while leaving the PFET transistor 100P exposed for further processing. Thereafter, one or more etching processes are performed to remove the exposed portion of the tensile stress-inducing layer 36 from above the PFET transistor 100P, while using the etch stop layer 32 as an etch-stop. The stress-inducing material layers 30, 36 contact one another in the area indicated by the dashed-oval region 50.

FIG. 1B depicts another illustrative embodiment of a semiconductor device 102 where stress-inducing material layers may be used to improve the performance of the device. The device 102 is generally comprised of an illustrative NFET transistor 100N and an illustrative PFET transistor 100P formed in and above an NFET region 10N and a PFET region 10P, respectively, defined in the substrate 10 by isolation regions 12. The view depicted in FIG. 1B is a cross-sectional view taken in the channel width direction of the devices 100N, 100P, as indicated by the double-arrow 40. In this example, the PFET device 100P has a longer channel width than does the NFET device 100N and the two devices 100N, 100P share a common gate structure 20, i.e., gate insulation layer 20A and gate electrode 20B. The NFET transistor 100N and the PFET transistor 100P each have a plurality of source/drain regions (not shown in the view depicted in FIG. 1B), a liner layer 25, sidewall spacers 26 and a metal silicide region 24 formed above the shared gate electrode 20B. In this example, the desired stress-inducing layer is formed above the NFET device 100N first, although, if desired, the first-stress inducing material layer could be formed above the PFET device 100P. Accordingly, FIG. 1B depicts a tensile stress-inducing layer 36, a compressive stress-inducing layer 30 and an etch stop layer 35 that are formed above the device 102. The layers 30, 36 and 32 may be formed from a variety of materials and they may be formed by performing a variety of known techniques. In one illustrative example, the stress-inducing layers 30, 36 are comprised of silicon nitride while the etch stop layer 35 is comprised of silicon dioxide.

The structure depicted in FIG. 1B may be achieved by a variety of different process flows. In one example, the tensile stress-inducing layer 36 and the etch stop layer 35 are blanket-deposited across both of the devices 100P, 100N. Thereafter, a masking layer (not shown), e.g., a photoresist mask, is formed on the device 102 to cover the NFET transistor 100N while leaving the portions of the tensile stress-inducing layer 36 and the etch stop layer 35 positioned above the PFET transistor 100P exposed for further processing. Thereafter, one or more etching processes are performed to remove the exposed portions of the tensile stress-inducing layer 36 and the etch stop layer 35 from above the PFET transistor 100P, wherein the metal silicide region 24 serves as an etch stop. Next, after the masking layer above the NFET device 100N is removed, the compressive stress-inducing layer 30 is blanket-deposited across both of the devices 100N, 100P. Thereafter, a masking layer (not shown), e.g., a photoresist mask, is formed on the device 102 to cover the PFET transistor 100P while leaving the NFET transistor 100N exposed for further processing. Thereafter, one or more etching processes are performed to remove the exposed portions of the compressive stress-inducing layer 30 from above the NFET transistor 100N, while using the etch stop layer 35 as an etch stop. As with the previous example, in this embodiment, the stress-inducing material layers 30, 36 contact one another in the area indicated by the dashed-oval region 50.

The present disclosure is directed to various methods of forming stress-inducing layers of material on semiconductor devices and the resulting devices.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming stress-inducing layers of material on semiconductor devices and the resulting devices. One illustrative device disclosed herein includes an NFET transistor a PFET transistor, a tensile stress-inducing layer formed above the NFET transistor, a compressive stress-inducing layer formed above the PFET transistor and a stress relaxation material positioned at least in an opening defined between the tensile stress-inducing layer and the compressive stress-inducing layer.

Yet another illustrative device disclosed herein includes an NFET transistor, a PFET transistor, a tensile stress-inducing layer formed above the NFET transistor, wherein the tensile stress-inducing layer has an intrinsic tensile stress level, and a compressive stress-inducing layer formed above the PFET transistor, wherein the compressive stress-inducing layer has an intrinsic compressive stress level. In this embodiment, the device further includes a stress relaxation material positioned at least in an opening defined between the tensile stress-inducing layer and the compressive stress-inducing layer, wherein the stress relaxation material has a lower absolute value of intrinsic stress than an absolute value of the intrinsic tensile stress level or the intrinsic compressive stress level.

One illustrative method disclosed herein includes forming a first stress-inducing layer of material above a gate structure for a first transistor, forming a second stress-inducing layer of material above a gate structure for a second transistor, wherein an edge of the second stress-inducing layer of material contacts an edge of the first stress-inducing layer of material along a contact region, and forming a patterned etch mask layer above the first and second stress-inducing layers, wherein the etch mask comprises an etch opening that is positioned above at least a portion of the contact region. In this embodiment, the method further includes performing an etching process through the etch mask to define an opening between the first and second stress-inducing layers, wherein the opening extends along at least a portion of the contact region and, after forming the opening, forming a stress relaxation material in the opening.

Another illustrative method disclosed herein includes depositing a stress-inducing layer of material above a gate structure for a first transistor and above a gate structure for a second transistor, performing a first etching process on the stress-inducing layer of material to define a first stress-inducing layer of material positioned above at least the gate structure of the first transistor, wherein the first stress-inducing layer of material has a first etched edge as a result of the first etching process, and depositing another stress-inducing layer of material above the first stress-inducing layer of material, the first gate structure and the second gate structure. In this embodiment, the method also includes the steps of performing a second etching process on the other stress-inducing layer of material to define a second stress-inducing layer of material positioned above at least the gate structure of the second transistor, the second stress-inducing layer of material having a second etched edge as a result of the second etching process, wherein the first and second etched edges define an opening between the first and second stress-inducing layers, and, after performing the second etching process, forming a stress relaxation material in the opening between the first and second stress-inducing layers.

Yet another illustrative method disclosed herein includes depositing a stress-inducing layer of material above a gate structure for a first transistor and above a gate structure for a second transistor, forming an etch stop layer above the stress-inducing layer of material and performing at least one etching process on the etch stop layer and the stress-inducing layer of material to define a first stress-inducing layer of material positioned above at least the gate structure of the first transistor and a patterned etch stop layer positioned above the first stress-inducing layer of material. This illustrative embodiment also includes the steps of performing a second etching process to remove a portion of the first stress-inducing layer from under the patterned etch stop layer which results in the formation of a recess positioned under the patterned etch stop layer, depositing a layer of stress relaxation material above the patterned etch stop layer, in the recess and above the gate structure of the second transistor, performing a third etching process to remove portions of the stress relaxation material that are positioned outside of the recess to thereby define a residual portion of the stress relaxation material, depositing another stress-inducing layer of material above the patterned etch stop layer, adjacent the residual portion of the stress relaxation material, above the first gate structure and above the second gate structure, and performing a fourth etching process on the other stress-inducing layer of material to define a second stress-inducing layer of material positioned above at least the gate structure of the second transistor and adjacent the residual portion of the stress relaxation material.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1B depict various illustrative examples of prior art semiconductor devices with various stress-inducing material layers being formed thereon;

FIGS. 2A-2F depict one illustrative novel process flow disclosed herein for forming stress-inducing layers of material on semiconductor devices;

FIGS. 3A-3D depict another illustrative novel process flow disclosed herein for forming stress-inducing layers of material on semiconductor devices;

FIGS. 4A-4E depict yet another illustrative novel process flow disclosed herein for forming stress-inducing layers of material on semiconductor devices; and

FIGS. 5A-5D depict various views of various illustrative embodiments of semiconductor devices disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming stress-inducing layers of material on semiconductor devices and the resulting devices. As will be readily apparent to those skilled in the art upon a complete reading of the present application, the methods and devices disclosed herein may be employed with a variety of technologies, e.g., NFET, PFET, CMOS, etc., and they may be used in manufacturing a variety of devices, including, but not limited to, logic devices, memory devices, resistors, conductive lines, etc. With reference to the attached figures, various illustrative embodiments of the methods and devices disclosed herein will now be described in more detail.

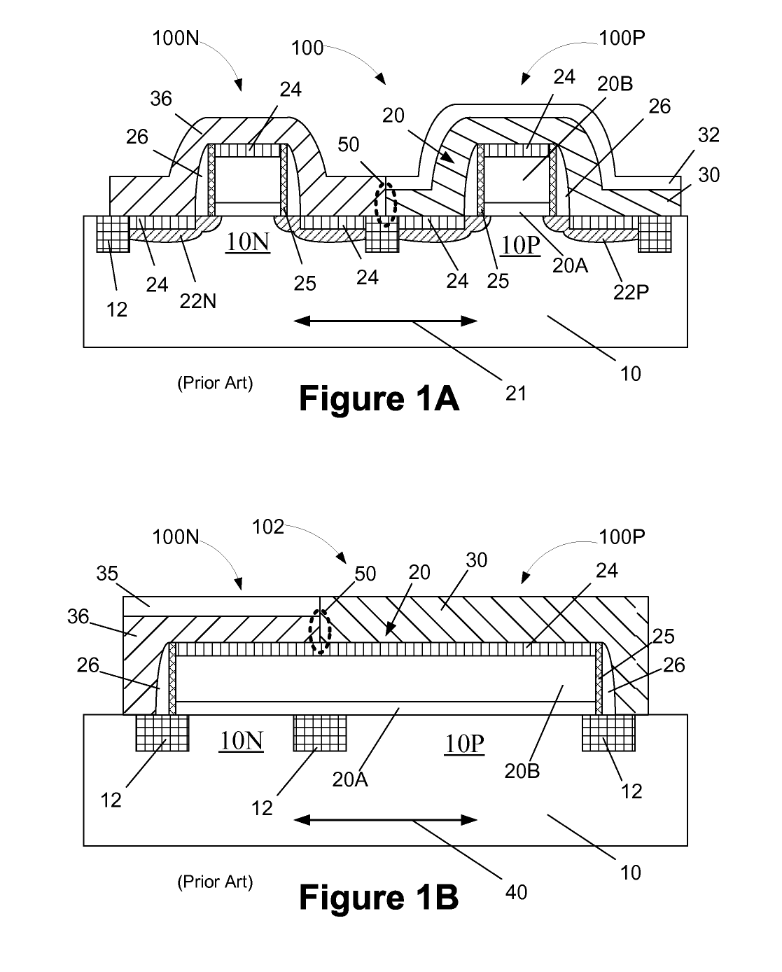

The inventors have discovered that physical contact between the stress-inducing material layers formed on semiconductor devices, such as in the contact region 50 depicted on the prior art devices shown in FIGS. 1A-1B, can have an adverse impact on the electrical performance characteristics of the transistors. The intrinsic stress in such stress-inducing material liners is transferred to adjacent areas by normal mechanical means. However, when a first stress-inducing material layer with a first type of stress (e.g., a tensile stress) contacts a second stress-inducing material layer with a second, opposite type stress (e.g., a compressive stress), it tends to degrade the tensile stress applied by the first stress-inducing material layer, i.e., the opposite stresses in the two stress-inducing layers interfere with each other in the local contact region between the two stress-inducing material layers. This local degradation in the stress applied by the stress-inducing material layers leads to a degradation of the transistor performance. The inventors have discovered that by de-coupling the stress-inducing material layers, or by locally relaxing the stress in one or more of the stress-inducing material layers in the area of contact, device performance can be increased.

As will be recognized by those skilled in the art after a complete reading of the present application, the stress engineering methods disclosed herein may be employed to improve the electrical performance of a variety of different semiconductor devices, e.g., transistors, resistors, etc. Thus, the term “semiconductor device” as used in the attached claims should not be considered to be limited to any particular type of device or structure. Notwithstanding the foregoing, for purposes of explanation and disclosing the inventions to the public, various illustrative process flows disclosed herein will involve formation of a tensile stress-inducing layer of material 230 above an illustrative NFET device 200N prior to the formation of a compressive stress-inducing layer of material 234 above an illustrative PFET device 200P. However, as will be recognized by those skilled in the art after a complete reading of the present application, the order in which the stress-inducing material layers are formed may be reversed if desired. Moreover, if desired, the compressive stress-inducing layer of material 234 may be formed above the NFET device 200N and the tensile stress-inducing layer of material 230 may be formed above the PFET device 200P. In one illustrative example, the stress-inducing layers 230, 234 are comprised of silicon nitride. Other materials, having approximately corresponding stress properties, may also be used to form the stress-inducing material layers 230, 234. The stress-inducing layers 230, 234 may have a thickness of about 50-60 nm, and they may be formed using a CVD process, wherein the parameters of the CVD process are adjusted and controlled such that the stress-inducing layers exhibit the desired intrinsic compressive stress or the desired intrinsic tensile stress, i.e., the stress in the layers of material after they are formed. The manner in which this is accomplished is well known to those skilled in the art. The purpose of the compressive stress-inducing layer 234 is to impart a desired compressive stress to the channel region of the PFET transistor 200P so as to increase the mobility of the charge carriers, i.e., holes, to thereby improve the electrical performance characteristics of the PFET transistor 200P. The purpose of the tensile stress-inducing layer 230 is to impart a desired tensile stress to the channel region of the NFET transistor 200N so as to increase the mobility of the charge carriers, i.e., electrons, to thereby improve the electrical performance characteristics of the NFET transistor 200N. The magnitude of the stress in each of the stress-inducing layers 230, 234 may vary depending upon the particular application, and the absolute value of the stress in each of the stress-inducing material layers 230, 234 may be different. Moreover, in some cases, multiple layers of stress-inducing material may be applied to a single device, e.g., a PFET transistor may have multiple compressive stress-inducing layers formed above the device and/or stress-inducing sidewall spacers may be formed on any type of transistor device. Thus, the inventions disclosed herein should not be considered as being limited to stress-inducing material layers of any particular form, type or material, and they should not be considered to be limited to the illustrative examples disclosed herein.

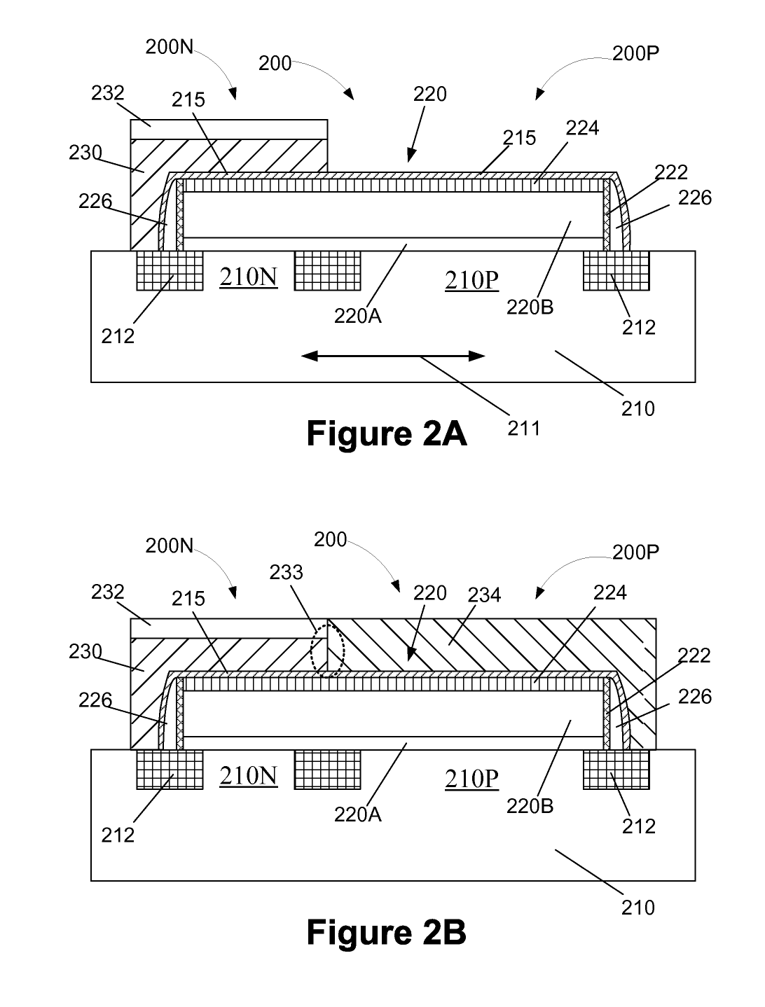

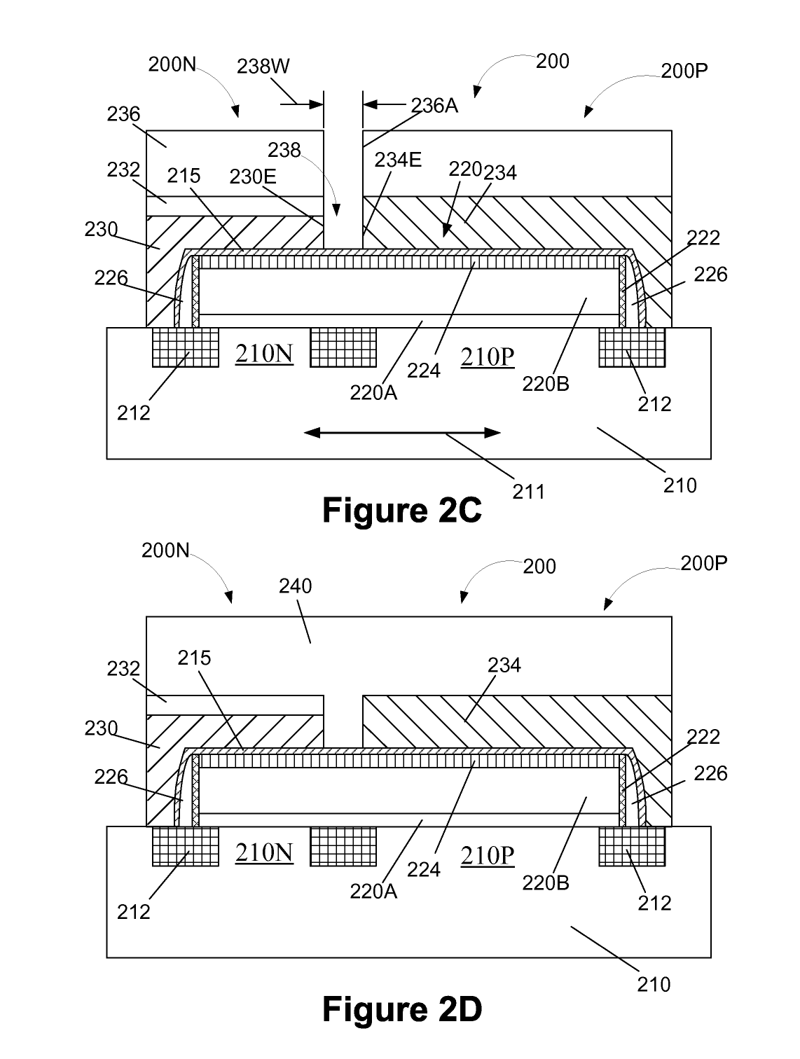

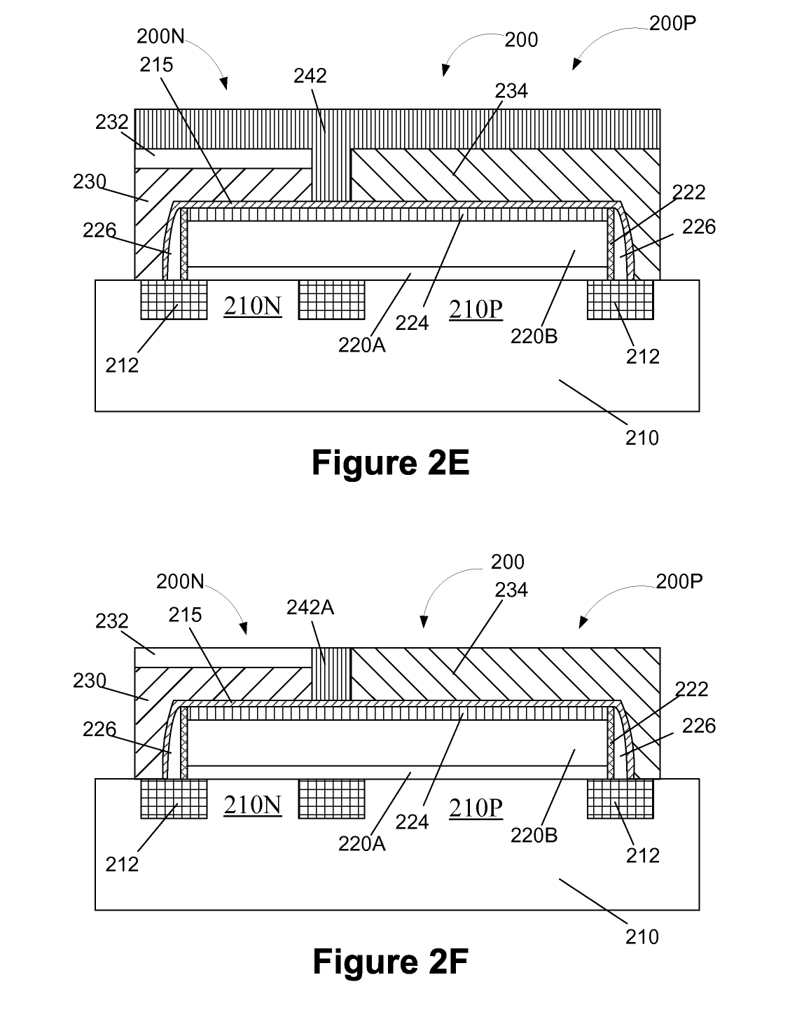

FIGS. 2A-2F depict one illustrative novel process flow disclosed herein for forming stress-inducing layers of material on semiconductor devices. FIG. 2A is a simplified view of an illustrative semiconductor device 200 at an early stage of manufacturing that is formed above a semiconducting substrate 210. The device 200 is generally comprised of an illustrative NFET transistor 200N and an illustrative PFET transistor 200P formed in and above an NFET region 210N and a PFET region 210P, respectively, of the substrate 210. The active regions 210N, 210P are defined by illustrative trench isolation structures 212 formed in the substrate 210. The view depicted in FIGS. 2A-2F is a cross-sectional view taken in the channel width direction of the devices 200N, 200P, as indicated by the double-arrow 211. In this example, the PFET device 200P has a longer channel width than does the NFET device 200N, and the two devices 200N, 200P share a common gate structure 220, i.e., the gate insulation layer 220A and the gate electrode 220B. As will be recognized by those skilled in the art after a complete reading of the present application, the gate structure 220 of the device 200, i.e., the gate insulation layer 220A and the gate electrode 220B, is intended to be representative in nature. That is, the gate structure 220 may be comprised of a variety of different materials and it may have a variety of configurations, and the gate structures 220 may be made using either so-called “gate-first” or “gate-last” techniques. For ease of explanation, the illustrative transistors 200N, 200P will be depicted as having a shared polysilicon gate electrode 220B, however, the present invention should not be considered as limited to such an illustrative embodiment. The substrate 210 may have a variety of configurations, such as the depicted bulk silicon configuration. The substrate 210 may also have a silicon-on-insulator (SOI) configuration that includes a bulk silicon layer, a buried insulation layer and an active layer, wherein semiconductor devices are formed in and above the active layer. The substrate 210 may also be made of materials other than silicon. Thus, the terms “substrate” or “semiconducting substrate” should be understood to cover all semiconductor structures and materials.

The NFET transistor 200N and the PFET transistor 200P each have a plurality of source/drain regions (not shown in the view depicted in FIGS. 2A-2F), a liner layer 222, sidewall spacers 226 and a metal silicide region 224 formed above the shared gate electrode 220B. In this example, the device 200 also includes an etch stop layer 215 that encapsulates the gate structure 220 and the spacers 226. One purpose of the etch stop layer 215 is to protect the sidewall spacers 226 during a subsequent etching process that is described more fully below. The etch stop layer 215 may be made of any of a variety of different materials that exhibit etch selectivity relative to the material of the stress-inducing layers 230, 234. In the case where the stress-inducing layers 230, 234 are comprised of silicon nitride, the etch stop layer 215 may be made of, for example, silicon dioxide. The etch stop layer 215 may be formed to any desired thickness, e.g., 5-7 nm, and it may be formed by performing a conformal CVD process.

The various structures and regions of the transistors depicted in FIGS. 2A-2F (and other drawings in this application) may be formed by performing well known processes. For example, the gate structure 220 shown in FIG. 2A may be formed by depositing various layers of material and thereafter performing one or more etching processes to define the basic layer stack of the gate structure 220. The liner layer 222 may be comprised of a relatively thin, e.g., 2-3 nm, layer of, for example, silicon dioxide, that is formed by performing a conformal CVD process. The spacer 226 may be formed by depositing a layer of spacer material, such as silicon nitride, and thereafter performing an anisotropic etching process on the layer of spacer material. The source/drain regions (not shown in FIGS. 2A-2F) may be formed using known ion implantation techniques using the appropriate dopant materials, i.e., N-type dopants and P-type dopants. The metal silicide region 224 may be formed by performing traditional silicidation processes, i.e., depositing a layer of refractory metal, performing a heating process causing the refractory metal to react with underlying silicon-containing material, removing unreacted portions of the layer of refractory metal (e.g., nickel, platinum or combinations thereof), followed perhaps by performing an additional heating process.

FIG. 2A depicts the device 200 after several process operations have been performed as it relates to the formation of the tensile stress-inducing layer 230 and an etch stop layer 232 above the NFET transistor 200N. Initially, the tensile stress-inducing layer 230 and the etch stop layer 232 were blanket deposited above the device 200. Thereafter, a masking layer (not shown), e.g., a photoresist mask, was formed on the device 200 to cover portions of the tensile stress-inducing layer 230 and the etch stop layer 232 that are positioned above the NFET transistor 200N, while leaving the portions of the tensile stress-inducing layer 230 and the etch stop layer 232 that are positioned above the PFET transistor 200P exposed for further processing. Thereafter, one or more etching processes, using different etch chemistries, are performed to remove the exposed portions of the tensile stress-inducing layer 230 and the etch stop layer 232 above the PFET transistor 200P. In one illustrative example, the etching processes may be dry, anisotropic etching processes. Then, the masking layer was removed to result in the structure depicted in FIG. 2A. The etch stop layer 232 may be made of any of a variety of different materials that exhibit etch selectivity relative to the material of the stress-inducing layers 230, 234. In the case where the stress-inducing layers 230, 234 are comprised of silicon nitride, the etch stop layer 232 may be made of, for example, silicon dioxide. The etch stop layer 232 may be formed to any desired thickness, e.g., 10-15 nm, and it may be formed by a performing a CVD process.

FIG. 2B depicts the device 200 after several process operations have been performed as it relates to the formation of the compressive stress-inducing layer 234 above the PFET transistor 200P. Initially, the compressive stress-inducing layer 234 was blanket deposited across the device 200 and above the etch stop layer 232. Thereafter, a masking layer (not shown), e.g., a photoresist mask, was formed on the device 200 to cover portions of the compressive stress-inducing layer 234 that are positioned above the PFET transistor 200P while leaving the portions of the compressive stress-inducing layer 234 that are positioned above the NFET transistor 200N exposed for further processing. Thereafter, one or more etching processes were performed to remove the exposed portions of the compressive stress-inducing layer 234. In one illustrative example, the etching processes may be dry, anisotropic etching processes. The etch stop layer 232 acts as an etch stop during this etching process and protects the underlying tensile stress-inducing layer 230. Then, the masking layer was removed to result in the structure depicted in FIG. 2B. In this example, at this point in fabrication, the stress-inducing layers of material 230, 234 engage and contact one another in the contact region 233.

FIG. 2C depicts the device 200 after several process operations have been performed. First, a patterned masking layer 236, e.g., a photoresist mask, was formed above the device 200 using traditional photolithography tools and techniques. The opening 236A in the masking layer 236 exposes at least a portion of the contact region 233 (See FIG. 2B) between the stress-inducing layers of material 230, 234. In some cases, the opening 236A in the masking layer 236 exposes the entirety of the contact region 233 between the stress-inducing layers of material 230, 234. Thereafter, one or more etching processes, using different etch chemistries, is performed through the masking layer 236 that ultimately stops on the etch stop layer 215. In one illustrative example, the etching processes may be dry, anisotropic etching processes. This etching process removes exposed portions of the etch stop layer 232, compressive stress-inducing layer 234 and the tensile stress-inducing layer 230 and defines an opening 238. The etching process results in the tensile stress-inducing layer 230 having an etched edge 230E and the compressive stress-inducing layer 234 having an etched edge 234E. The width 238W of the opening 238 in the channel width direction 211 may vary depending upon the particular application, e.g., 10-40 nm. The opening 238, where it is formed, effectively decouples the two stress-inducing layers of material 230, 234 from one another.

The next process operation involves filling at least the opening 238 with stress relaxation material. Depending upon the device under construction and the particular process flow involved, the stress relaxation material may be any type of material, e.g., silicon dioxide, silicon nitride, silicon oxynitride, a low-k material (k-value less than about 3.5), etc. In some applications, all or a portion of the opening 238 may not be filled with a material, e.g., an air-gap may be formed in the opening 238. In general, the stress relaxation material should be a material that is formed such that it has little, if any, intrinsic stress level, or at least an intrinsic stress level that is much less as compared to the intrinsic stress levels in the stress-inducing layers of material 230, 234. In current day devices, the stress-inducing layers of material 230, 234 may be formed so as to have an inherent stress (after forming) that falls within the range of 1-5 GPa, depending upon the particular application. In such a situation, the stress relaxation material should be targeted so as to have an intrinsic stress level that is not greater than about 100 MPa. That is, the absolute value of the intrinsic stress level within the stress relaxation material should be less than the absolute value of the intrinsic stress level in either of the stress-inducing layers of material 230, 234.

FIG. 2D depicts the device 200 after one illustrative example of a stress relaxation material has been formed to fill the opening 238. In this illustrative example, the stress relaxation material is a interlayer dielectric material 240, such as silicon dioxide, etc. As noted above, in this application, all or a portion of the opening 238 may not be filled with the dielectric material 240, e.g., an air-gap may be formed in the opening 238. The interlayer dielectric material 240 may be initially blanket deposited across the device 200 and in the opening 238. Thereafter, a chemical mechanical polishing process was performed on the interlayer dielectric material to result in the structure depicted in FIG. 2D.

FIGS. 2E-2F depict the device 200 after another illustrative example of a stress relaxation material has been formed to fill the opening 238. In this illustrative example, the stress relaxation material is layer of material 242, such as silicon nitride or other materials that have approximately corresponding stress properties. The layer of material 242 may be initially blanket deposited across the device 200 and in the opening 238. In one illustrative embodiment, the layer of material 242 is a layer of silicon nitride that is formed such that it exhibits little, if any, inherent stress. Thereafter, an etch-back process e.g., a dry or wet etching, was performed to remove excess portions of the layer of material 242, thereby leaving a residual portion 242A of the layer of material 242 in the opening 238, as depicted in FIG. 2F.

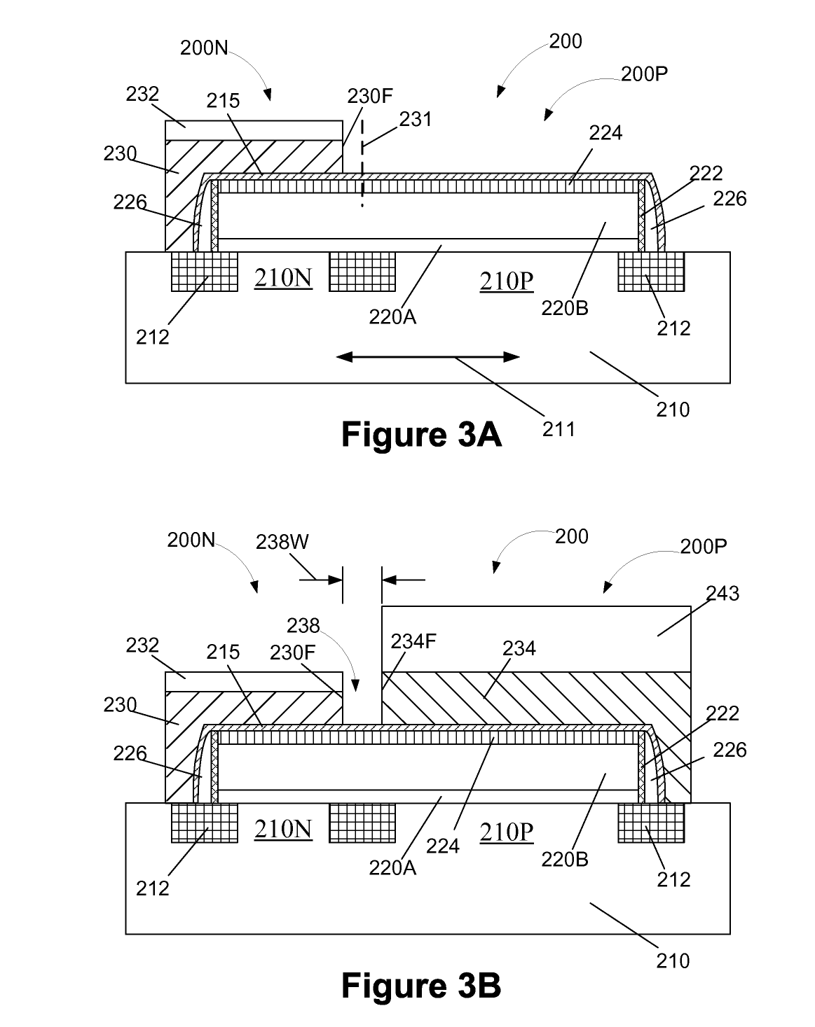

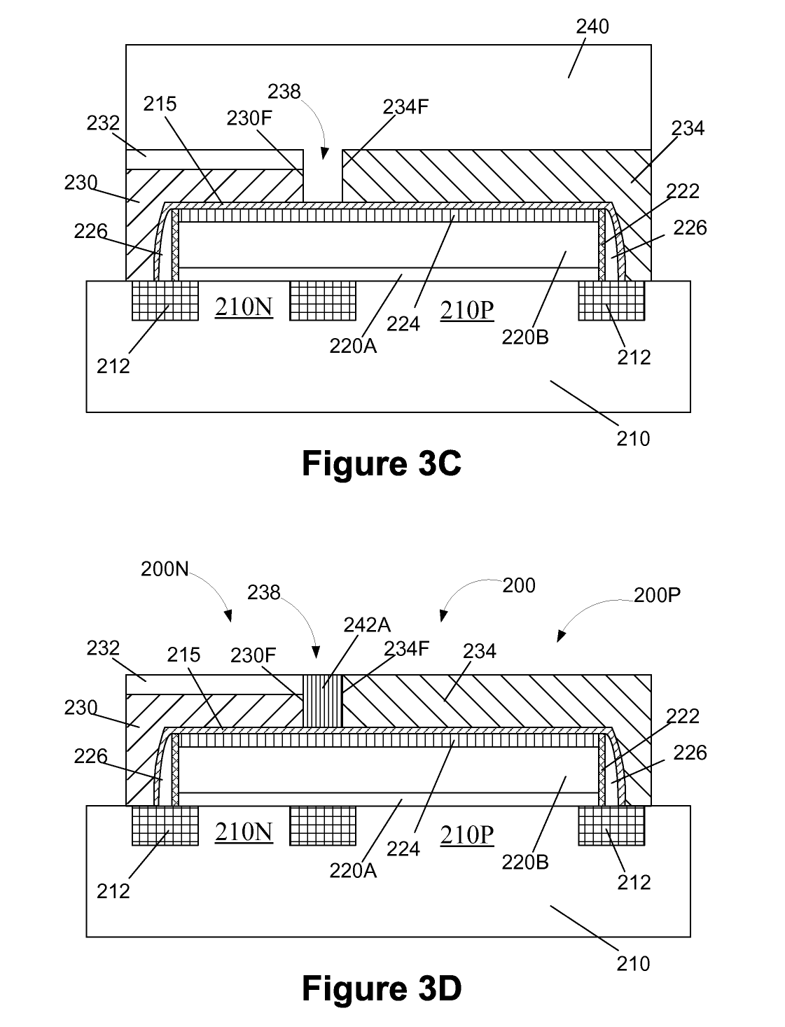

FIGS. 3A-3D depict another illustrative novel process flow disclosed herein for forming stress-inducing layers of material on semiconductor devices. The basic structure of the transistor devices depicted in FIGS. 3A-3D is the same as that previously described with respect to the device 200 depicted in FIG. 2A. FIG. 3A depicts the device 200 after several process operations have been performed as it relates to the formation of the tensile stress-inducing layer 230 and an etch stop layer 232 above the NFET transistor 200N. Initially, the tensile stress-inducing layer 230 and the etch stop layer 232 were blanket deposited above the device 200. Thereafter, a masking layer (not shown), e.g., a photoresist mask, was formed on the device 200 to cover portions of the tensile stress-inducing layer 230 and the etch stop layer 232 that are positioned above the NFET transistor 200N, while leaving the portions of the tensile stress-inducing layer 230 and the etch stop layer 232 that are positioned above the PFET transistor 200P exposed for further processing. Thereafter, one or more etching processes, using different etch chemistries, are performed to remove the exposed portions of the tensile stress-inducing layer 230 and the etch stop layer 232. In one illustrative example, the etching processes may be dry, anisotropic etching processes. However, in this process flow, the masking layer is sized such that the edge 230F of the tensile stress-inducing layer 230 does not extend as far toward the PFET transistor 200P as would be the case where the stress-inducing layers of material 230, 234 are formed so as to contact one another. That is, using prior art techniques, the tensile stress-inducing layer 230 would be patterned such that its edge 230F would be positioned at the approximate location indicated by the dashed line 231. In this case, the tensile stress-inducing layer 230 is initially patterned so as to define one-half of the opening 238 where the stress relaxation material will be positioned, as described more fully below. Then, the masking layer was removed to result in the structure depicted in FIG. 3A.

FIG. 3B depicts the device 200 after several process operations have been performed as it relates to the formation of the compressive stress-inducing layer 234 above the PFET transistor 200P. Initially, the compressive stress-inducing layer 234 was blanket deposited across the device 200 and above the etch stop layer 232. Thereafter, a masking layer 243, e.g., a photoresist mask, was formed on the device 200 to cover portions of the compressive stress-inducing layer 234 that are positioned above the PFET transistor 200P, while leaving the portions of the compressive stress-inducing layer 234 that are positioned above the NFET transistor 200N exposed for further processing. Thereafter, one or more etching processes were performed to remove the exposed portions of the compressive stress-inducing layer 234. In one illustrative example, the etching processes may be dry, anisotropic etching processes. However, in this process flow, the masking layer 243 is sized such that the edge 234F of the compressive stress-inducing layer 234 does not extend as far toward the NFET transistor 200N as would be the case where the stress-inducing layers of material 230, 234 are formed so as to contact one another. That is, using prior art techniques, the compressive stress-inducing layer 234 would be patterned such that its edge 234F would be positioned at the approximate location indicated by the dashed line 231. In this case, the compressive stress-inducing layer 234 is initially patterned so as to define the other half of the opening 238 where the stress relaxation material will be positioned, as described more fully below. Note, that in this embodiment, after the initial patterning of the stress-inducing layers of material 230, 234, there is no contact between the stress-inducing layers of material 230, 234.

FIGS. 3C and 3D depict the device 200 after the stress relaxation material has been formed in the opening 238. More specifically, FIG. 3C depicts the case where the interlayer dielectric material 240 is used to fill the opening 238, as described above. FIG. 3D depicts the case where a layer of silicon nitride is formed and etched back, as described above, to result in the residual portion 242A being positioned in the opening 238.

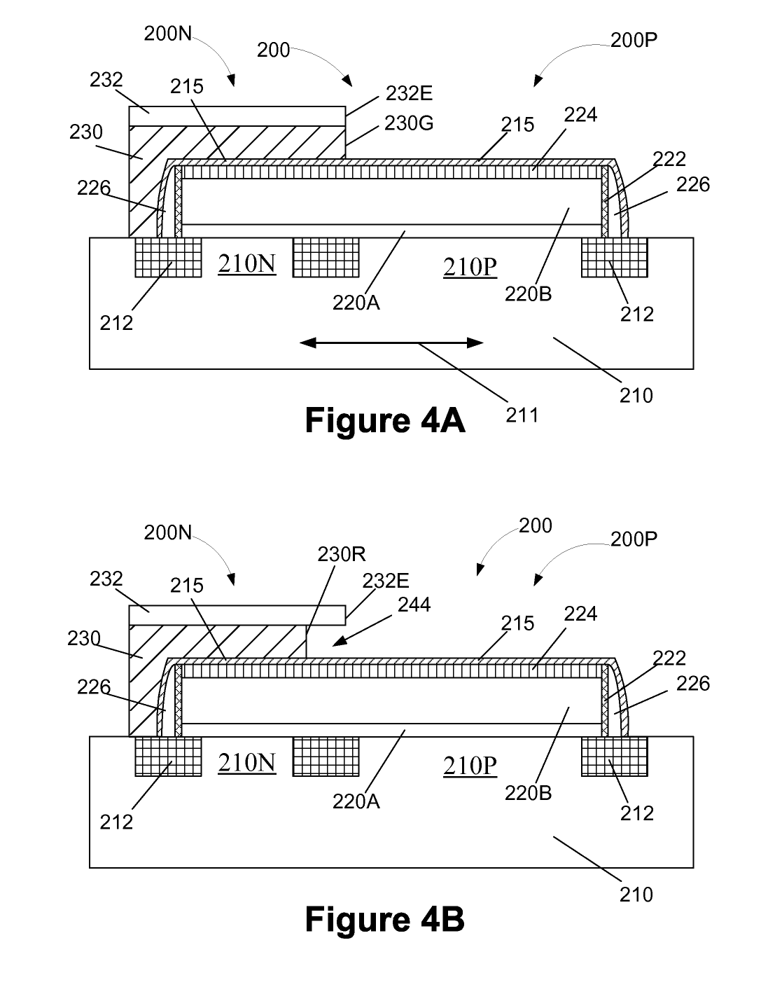

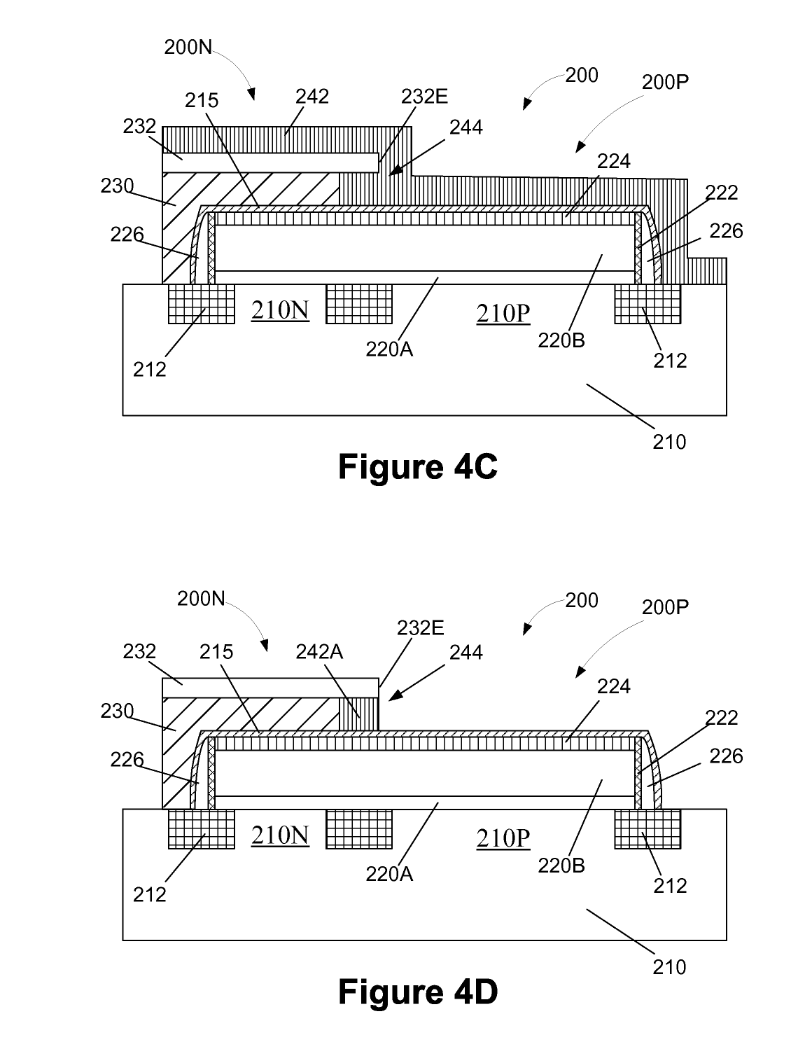

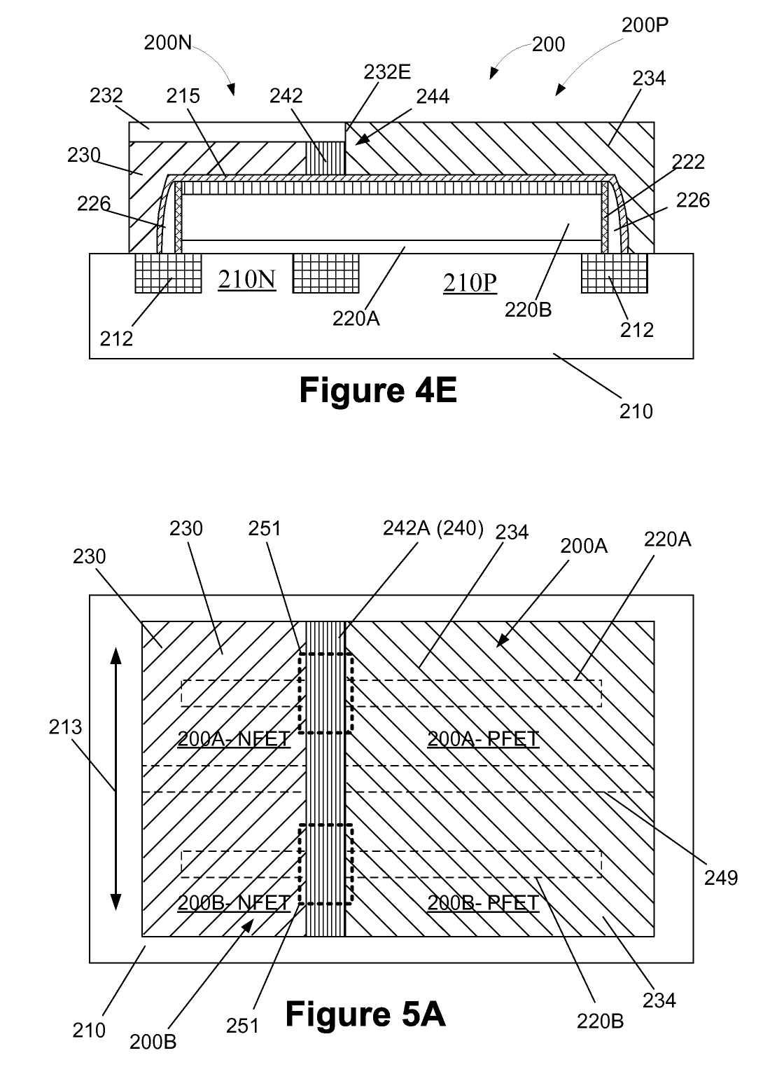

FIGS. 4A-4E depict yet another illustrative novel process flow disclosed herein for forming stress-inducing layers of material on semiconductor devices. The basic structure of the transistor devices depicted in FIGS. 4A-4E is the same as that previously described with respect to the device 200 depicted in FIG. 2A. FIG. 4A depicts the device 200 after the tensile stress-inducing layer 230 and an etch stop layer 232 were formed above the NFET transistor 200N as described above with respect to FIG. 2A. This process results in the tensile stress-inducing layer 230 having an initial etched edge 230G and the etch stop layer 232 having an initial etched edge 232E.

Thereafter, as shown in FIG. 4B, an etching process is performed to remove portions of the tensile stress-inducing layer 230 so as to define a recess 244 positioned under the etch stop layer 232. In one illustrative example, this etching process may be a wet etching process. This etching process results in the tensile stress-inducing layer 230 having a recessed edge 230R. The lateral width of the recess 244 may be about the same as the width of the opening 238 described previously.

Next, as shown in FIG. 4C, one illustrative example of a stress relaxation material has been formed to fill the recess 244. In this illustrative example, the stress relaxation material is the previously described layer of material 242. The layer of material 242 may be initially formed across the device 200 and in the recess 244. In one illustrative embodiment, the layer of material 242 is a layer of silicon nitride that is formed by a very conformal atomic layer deposition (ALD) process and it may be formed such that it exhibits little, if any, intrinsic stress. In some applications, all or a portion of the recess 244 may not be filled with a material, e.g., an air-gap may be formed in the recess 242.

Thereafter, as shown in FIG. 4D, a wet etching process was performed to remove portions of the layer of material 242 not protected by the etch stop layer 232, thereby leaving a residual portion 242A of the layer of material 242 in the recess 244.

FIG. 4E depicts the device 200 after the compressive stress-inducing layer 234 has been formed above the PFET transistor 200P. Initially, the compressive stress-inducing layer 234 was blanket deposited across the device 200 and above the etch stop layer 232. Thereafter, a masking layer (not shown), e.g., a photoresist mask, was formed on the device 200 to cover portions of the compressive stress-inducing layer 234 that are positioned above the PFET transistor 200P, while leaving the portions of the compressive stress-inducing layer 234 that are positioned above the NFET transistor 200N exposed for further processing. Thereafter, one or more etching processes were performed to remove the exposed portions of the compressive stress-inducing layer 234. The etch stop layer 232 acts to protect the tensile stress-inducing layer 230 and the residual portion 242A of the layer of material 242 during this process.

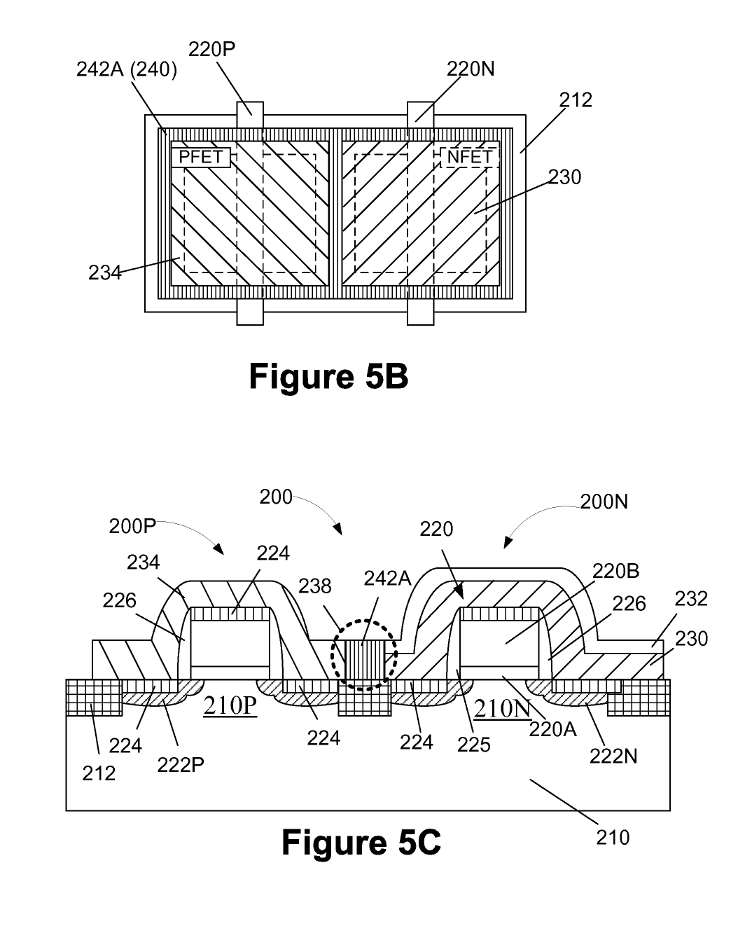

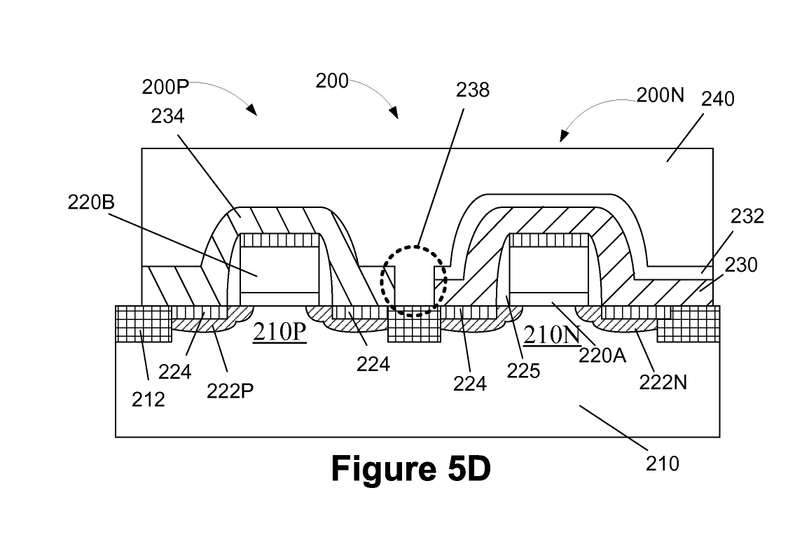

FIGS. 5A-5D depict various illustrative semiconductor devices wherein illustrative examples of some configurations of the stress relaxation materials disclosed herein may be employed. FIG. 5A is a simplistic, plan view depiction of an illustrative integrated circuit product comprised of two of the devices 200 (designated 200A, 200B) that are formed above the substrate 210 and laterally isolated from one another by a schematically depicted isolation structure 249 formed in the substrate 210. Each of the devices 200A, 200B comprises an NFET transistor and a PFET transistor that share a common gate electrode (220A, 220B). As can be seen in FIG. 5A, a tensile stress-inducing layer 230 has been formed above the NFET transistors, while a compressive stress-inducing layer 234 has been formed above the PFET transistors (note the cross-section lining for the stress-inducing layers of material 230, 234 has been employed in FIG. 5A view in an effort to facilitate explanation). Also depicted in FIG. 5A is a region of stress relaxation material 242A, 240 positioned between the stress-inducing layers of material 230, 234. Note that, in this embodiment, there is no stress relaxation material positioned between the adjacent PFET transistors that “share” the compressive stress-inducing layer 234 or between the adjacent NFET transistors that “share” the tensile stress-inducing layer 230, although the stress relaxation material could be formed in such location if desired. Note that, in this embodiment, the stress relaxation material is formed so as to separate the stress-inducing layers of material 230, 234 across the entire length of the devices in the channel length direction, as indicated by the double arrows 213. However, such complete separation may not be required in all applications. For example, in some cases, it may be sufficient for the stress relaxation material to only span the region 251 proximate the gate structures of the devices, as shown in FIG. 5A.

FIG. 5B is a simplistic, plan view depiction of another illustrative integrated circuit product comprised of an NFET transistor and a PFET transistor each with its own gate structure 220N, 220P, respectively. The transistors are isolated from one another by a schematically depicted isolation structure 212 (the inner boundary of which is depicted by a dashed lines). As can be seen in FIG. 5B, a tensile stress-inducing layer 230 has been formed above the NFET transistor, while a compressive stress-inducing layer 234 has been formed above the PFET transistor (note the cross-section lining for the stress-inducing layers of material 230, 234 has been employed in FIG. 5B in an effort to facilitate explanation). Also depicted in FIG. 5B is a region of stress relaxation material 242A, 240 that effectively surrounds each of the transistors.

FIGS. 5C-5D are cross-sectional views of an illustrative semiconductor device 200 taken in the channel length direction showing the location of the stress relaxation material 242A, 240 when the transistors are arranged in side-by side configuration as depicted in FIG. 5B. The device 200 is generally comprised an illustrative a NFET transistor 200N and an illustrative PFET transistor 200P formed in and above an NFET region 210N and a PFET region 210P, respectively. The NFET transistor 200N and the PFET transistor 200P each include a schematically depicted gate electrode structure 220, that typically includes a gate insulation layer 220A and a gate electrode 220B, and a plurality of source/drain regions 222N, 222P, respectively, sidewall spacers 226, and a plurality of metal silicide regions 224. FIGS. 5C and 5D depict the device 200 after the stress relaxation material has been formed in the opening 238. More specifically, FIG. 5C depicts the case where a layer of silicon nitride is formed and etched back, as described above, to result in the residual portion 242A being positioned in the opening 238. FIG. 5D depicts the case where the interlayer dielectric material 240 is used to fill the opening 238, as described above.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A device, comprising:
an NFET transistor;
a PFET transistor;
a tensile stress-inducing layer formed above said NFET transistor;
a compressive stress-inducing layer formed above said PFET transistor; and
a stress relaxation material positioned at least in an opening defined between said tensile stress-inducing layer and said compressive stress-inducing layer.

2. The device of claim 1, wherein said tensile stress-inducing layer and said compressive stress-inducing layer are comprised of silicon nitride.

3. The device of claim 1, wherein said stress relaxation material completely separates said tensile stress-inducing layer from said compressive stress-inducing layer.

4. The device of claim 1, wherein said NFET transistor and said PFET transistor share a common gate structure and wherein at least a portion of said stress relaxation material is positioned above at least said common gate structure.

5. The device of claim 1, wherein said NFET transistor and said PFET transistor share a common gate structure and wherein said stress relaxation material extends, in a channel length direction, across an entire width of said NFET transistor and said PFET transistor.

6. The device of claim 1, wherein said NFET transistor and said PFET transistor share a common gate structure and wherein at least a portion of said stress relaxation material is positioned above an isolation structure that separates said NFET transistor and said PFET transistor.

7. The device of claim 1, wherein said tensile stress-inducing layer and said compressive stress-inducing layer have different thicknesses.

8. The device of claim 1, wherein said stress relaxation material is comprised of a material that exhibits an intrinsic stress, the absolute value of which is less than an absolute value of an intrinsic stress of either said tensile stress-inducing layer or said compressive stress-inducing layer.

9. The device of claim 1, wherein said stress relaxation material exhibits an intrinsic stress level, the absolute value of which is less than 100 MPa.

10. The device of claim 1, wherein said stress relaxation material is a layer of silicon nitride with an intrinsic stress level of approximately zero.

11. A device, comprising:
an NFET transistor;
a PFET transistor;
a tensile stress-inducing layer formed above said NFET transistor, said tensile stress-inducing layer having an intrinsic tensile stress level;
a compressive stress-inducing layer formed above said PFET transistor, said compressive stress-inducing layer having an intrinsic compressive stress level; and
a stress relaxation material positioned at least in an opening defined between said tensile stress-inducing layer and said compressive stress-inducing layer, wherein said stress relaxation material has an intrinsic stress, the absolute value of which is less than an absolute value of said intrinsic tensile stress level or said intrinsic compressive stress level.

12. The device of claim 11, wherein said stress relaxation material completely separates said tensile stress-inducing layer from said compressive stress-inducing layer.

13. The device of claim 11, wherein said NFET transistor and said PFET transistor share a common gate structure and wherein at least a portion of said stress relaxation material is positioned above at least said common gate structure.

14. The device of claim 11, wherein said NFET transistor and said PFET transistor share a common gate structure and wherein said stress relaxation material extends, in a channel length direction, across an entire width of said NFET transistor and said PFET transistor.

15. The device of claim 11, wherein said NFET transistor and said PFET transistor share a common gate structure and wherein at least a portion of said stress relaxation material is positioned above an isolation structure that separates said NFET transistor and said PFET transistor.

16. A method, comprising:
forming a first stress-inducing layer of material above a gate structure for a first transistor;
forming a second stress-inducing layer of material above a gate structure for a second transistor, wherein an edge of said second stress-inducing layer of material contacts an edge of said first stress-inducing layer of material along a contact region;
forming a patterned etch mask layer above said first and second stress-inducing layers, wherein said etch mask comprises an etch opening that is positioned above at least a portion of said contact region;
performing an etching process through said etch mask to define an opening between said first and second stress-inducing layers, wherein said opening extends along at least a portion of said contact region; and
after forming said opening, forming a stress relaxation material in said opening.

17. The method of claim 16, wherein said first transistor is an NFET transistor, said first stress-inducing layer of material is a tensile stressed layer of material, said second transistor is a PFET transistor and said second stress-inducing layer of material is a compressive stressed layer of material.

18. The method of claim 16, wherein said first transistor is a PFET transistor, said first stress-inducing layer of material is a compressive stressed layer of material, said second transistor is an NFET transistor and said second stress-inducing layer of material is a tensile stressed layer of material.

19. The method of claim 16, wherein said opening between said first and second stress-inducing layers extends along the entire length of said contact region.

20. The method of claim 16, wherein forming said stress relaxation material in said opening between said first and second stress-inducing layers comprises overfilling said opening between said first and second stress-inducing layers with an interlayer dielectric material and performing a chemical mechanical polishing process on said interlayer dielectric material.

21. The method of claim 16, wherein forming said stress relaxation material in said opening between said first and second stress-inducing layers comprises overfilling said opening between said first and second stress-inducing layers with a layer of silicon nitride and performing an etching process on said layer of silicon nitride to remove portions of said layer of silicon nitride positioned outside of said opening between said first and second stress-inducing layers.

22. The method of claim 16, wherein said first transistor is an NFET transistor, said first stress-inducing layer of material is a compressive stressed layer of material, said second transistor is a PFET transistor and said second stress-inducing layer of material is a tensile stressed layer of material.

23. The method of claim 16, wherein said first transistor is a PFET transistor, said first stress-inducing layer of material is a tensile stressed layer of material, said second transistor is an NFET transistor and said second stress-inducing layer of material is a compressive stressed layer of material.

24. A method, comprising:
depositing a stress-inducing layer of material above a gate structure for a first transistor and above a gate structure for a second transistor;
performing a first etching process on said stress-inducing layer of material to define a first stress-inducing layer of material positioned above at least said gate structure of said first transistor, said first stress-inducing layer of material having a first etched edge as a result of said first etching process;
depositing another stress-inducing layer of material above said first stress-inducing layer of material, said first gate structure and said second gate structure;
performing a second etching process on said another stress-inducing layer of material to define a second stress-inducing layer of material positioned above at least said gate structure of said second transistor, said second stress-inducing layer of material having a second etched edge as a result of said second etching process, wherein said first and second etched edges define an opening between said first and second stress-inducing layers; and
after performing said second etching process, forming a stress relaxation material in said opening between said first and second stress-inducing layers.

25. The method of claim 24, wherein said first transistor is an NFET transistor, said first stress-inducing layer of material is a tensile stressed layer of material, said second transistor is a PFET transistor and said second stress-inducing layer of material is a compressive stressed layer of material.

26. The method of claim 24, wherein said first transistor is a PFET transistor, said first stress-inducing layer of material is a compressive stressed layer of material, said second transistor is an NFET transistor and said second stress-inducing layer of material is a tensile stressed layer of material.

27. The method of claim 24, wherein forming said stress relaxation material in said opening comprises overfilling said opening with an interlayer dielectric material and performing a chemical mechanical polishing process on said interlayer dielectric material.

28. The method of claim 24, wherein forming said stress relaxation material in said opening comprises overfilling said opening with a layer of silicon nitride and performing an etching process on said layer of silicon nitride to remove portions of said layer of silicon nitride positioned outside of said opening.

29. The method of claim 24, wherein said first transistor is an NFET transistor, said first stress-inducing layer of material is a compressive stressed layer of material, said second transistor is a PFET transistor and said second stress-inducing layer of material is a tensile stressed layer of material.

30. The method of claim 24, wherein said first transistor is a PFET transistor, said first stress-inducing layer of material is a tensile stressed layer of material, said second transistor is an NFET transistor and said second stress-inducing layer of material is a compressive stressed layer of material.

31. A method, comprising:
depositing a stress-inducing layer of material above a gate structure for a first transistor and above a gate structure for a second transistor;
forming an etch stop layer above said stress-inducing layer of material;
performing at least one first etching process on said etch stop layer and said stress-inducing layer of material to define a first stress-inducing layer of material positioned above at least said gate structure of said first transistor and a patterned etch stop layer positioned above said first stress-inducing layer of material;
performing a second etching process to remove a portion of said first stress-inducing layer from under said patterned etch stop layer, said second etching process resulting in a recess positioned under said patterned etch stop layer;
depositing a layer of stress relaxation material above said patterned etch stop layer, in said recess and above said gate structure of said second transistor;
performing a third etching process to remove portions of said stress relaxation material that are positioned outside of said recess to thereby define a residual portion of said stress relaxation material;
depositing another stress-inducing layer of material above said patterned etch stop layer, adjacent said residual portion of said stress relaxation material, above said first gate structure and above said second gate structure; and
performing a fourth etching process on said another stress-inducing layer of material to define a second stress-inducing layer of material positioned above at least said gate structure of said second transistor and adjacent said residual portion of said stress relaxation material.

32. The method of claim 31, wherein said first transistor is an NFET transistor, said first stress-inducing layer of material is a tensile stressed layer of material, said second transistor is a PFET transistor and said second stress-inducing layer of material is a compressive stressed layer of material.

33. The method of claim 31, wherein said first transistor is a PFET transistor, said first stress-inducing layer of material is a compressive stressed layer of material, said second transistor is an NFET transistor and said second stress-inducing layer of material is a tensile stressed layer of material.

34. The method of claim 31, wherein said first transistor is an NFET transistor, said first stress-inducing layer of material is a compressive stressed layer of material, said second transistor is a PFET transistor and said second stress-inducing layer of material is a tensile stressed layer of material.

35. The method of claim 31, wherein said first transistor is a PFET transistor, said first stress-inducing layer of material is a tensile stressed layer of material, said second transistor is an NFET transistor and said second stress-inducing layer of material is a compressive stressed layer of material.

36. An integrated circuit product, comprising:
a first semiconductor device;
a second semiconductor device;
a first stress-inducing layer formed above said first semiconductor device, said first stress-inducing layer exhibiting a first type of stress;
a second stress-inducing layer formed above said second semiconductor device, said second stress-inducing layer exhibiting a second type of stress that is opposite of said first type of stress; and
a stress relaxation material positioned at least in an opening defined between said first stress-inducing layer and said second stress-inducing layer.

37. The product of claim 36, wherein said first semiconductor device is a transistor or a resistor.

38. The product of claim 36, wherein said second semiconductor device is a transistor or a resistor.

39. The product of claim 36, wherein said first type of stress is a tensile stress and said second type of stress is a compressive stress.

40. The product of claim 36, wherein said first type of stress is a compressive stress and said second type of stress is a tensile stress.

41. A device, comprising:
an NFET transistor;
a PFET transistor;
a first stress-inducing layer formed above said NFET transistor, said first stress-inducing layer exhibiting a first type of stress;
a second stress-inducing layer formed above said PFET transistor, said second stress-inducing layer exhibiting a second type of stress that is opposite of said first type of stress; and
a stress relaxation material positioned at least in an opening defined between said first stress-inducing layer and said second stress-inducing layer.

42. The device of claim 41, wherein said first type of stress is a tensile stress and said second type of stress is a compressive stress.

43. The device of claim 41, wherein said first type of stress is a compressive stress and said second type of stress is a tensile stress.
